(19) United States
(12) Patent Application Publication
(10) Pub. No.: US 2024/0345157 A1
(43) Pub. Date: Oct. 17, 2024

(54) TEST METHOD AND TEST DEVICE FOR IDENTIFYING CRITICAL POINTS OF A CIRCUIT DESIGN IN A POST-SILICON STAGE

(71) Applicant: MEDIATEK INC., Hsin-Chu (TW)

(72) Inventors: Harry Hai Chen, Hsinchu City (TW); Jeng-Yu Liao, Hsinchu City (TW)

(73) Assignee: MEDIATEK INC., Hsin-Chu (TW)

(21) Appl. No.: 18/633,564

(22) Filed: Apr. 12, 2024

Related U.S. Application Data
(60) Provisional application No. 63/496,039, filed on Apr. 14, 2023.

(51) Int. Cl. G01R 31/28

(52) U.S. Cl. CPC G01R 31/2884; G01R 31/2834

(57) ABSTRACT

A test method is provided for testing a circuit design. The test method includes inputting T test patterns into M sample chips to generate M test results where each sample chip is implemented with the circuit design and has N sensor positions, obtaining M mismatch counts of each sensor position according to the M test results, obtaining a mismatch parameter of the each sensor position according to the M mismatch counts of the each sensor position, selecting m sample chips from the M sample chips according to the M mismatch counts and the mismatch parameter of the each sensor position, selecting m test results from the M test results according to the m sample chips, and analyzing the m test results to obtain at least one critical point of the circuit design. M>m, and T, M, N and m are positive integers.

### CROSS REFERENCE TO RELATED APPLICATIONS

This application claims the benefit of U.S. Provisional Application No. 63/496,039, filed on Apr. 14, 2023. The content of the application is incorporated herein by reference.

### BACKGROUND

In the field of integrated circuits (ICs), the minimum operating voltage (noted as Vmin in the text) of an IC is an important feature. An IC will fail to function correctly if the applied voltage falls below the minimum operating voltage Vmin. Consequently, ICs with a lower minimum operating voltage Vmin are less susceptible to failure under low voltage conditions. This makes the reduction of an IC's minimum operating voltage Vmin a crucial objective in circuit design.

During the design process, the IC's design file can be analyzed at a pre-silicon stage (before manufacturing) to identify circuit locations more sensitive to the operating voltage, termed as “critical points”. Efforts can be made to lower the circuit's minimum operating voltage Vmin by adjusting circuit settings (e.g. placement and routing) of these critical points.

Practical experience indicates that despite thorough checks of an IC's design file during the pre-silicon stage, some critical points may remain undetected. These critical points can cause the IC to become sensitive to the operating voltage after the IC has been manufactured (in a post-silicon stage), which is not conducive to reducing the IC's minimum operating voltage Vmin.

An alternative approach involves the incorporation of timing margin sensors into pre-silicon critical paths for subsequent post-silicon validation. The circuitry of these sensors necessitates an area cost, thereby limiting the number of sensors that can be inserted. This restriction results in a reduced coverage of sensor checks on the integrated circuit (IC), hindering the execution of validation with high accuracy and high coverage. It is also difficult to place sensors in the proper locations to detect critical points and critical paths which are more sensitive to the operating voltage. Therefore, in this field, there is still a lack of solution for finding real critical points sensitive to the operating voltage in a post-silicon stage.

### Summary

An embodiment provides a test method for testing a circuit design. The test method includes inputting T test patterns into M sample chips to generate M test results where each sample chip is implemented with the circuit design and has N sensor positions, obtaining M mismatch counts of each sensor position according to the M test results, obtaining a mismatch parameter of the each sensor position according to the M mismatch counts of the each sensor position, selecting m sample chips from the M sample chips according to the M mismatch counts and the mismatch parameter of the each sensor position, selecting m test results from the M test results according to the m sample chips, and analyzing the m test results to obtain at least one critical point of the circuit design. M>m, and T, M, N and m are positive integers.

Another embodiment provides a test device for testing a circuit design. The test device includes a test pattern unit and a processing unit. The test pattern unit is used to input T test patterns into M sample chips to generate M test results, where the M sample chips are implemented with the circuit design, and each sample chip has N sensor positions. The processing unit is used to receive the M test results, obtain M mismatch counts of each sensor position according to the M test results, obtain a mismatch parameter of the each sensor position according to the M mismatch counts of the each sensor position, select m sample chips from the M sample chips according to the M mismatch counts and the mismatch parameter of the each sensor position, select m test results from the M test results according to the m sample chips, and analyze the m test results to obtain at least one critical point of the circuit design. M>m, and T, M, N and m are positive integers.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a test device for testing a circuit design according to an embodiment.

FIG. 2 illustrates a test method for the test device of FIG. 1.

FIG. 3 illustrates a distribution of mismatch parameters of mismatch counts of a plurality of sensor positions in an example.

FIG. 4 illustrates a distribution of the sample chips of FIG. 1 according to the minimum operating voltages of the sample chips.

FIG. 5 illustrates distributions of mismatch parameters and mismatch counts for sensor positions of the sample chips in the first bin of FIG. 4.

FIG. 6 illustrates distributions of mismatch parameters and mismatch counts for sensor positions of the sample chips in the second bin of FIG. 4.

FIG. 7 illustrates distributions of mismatch parameters and mismatch counts for sensor positions of the sample chips in the third bin of FIG. 4.

FIG. 8 illustrates distributions of mismatch parameters and mismatch counts for sensor positions of the sample chips in the fourth bin of FIG. 4.

FIG. 9 illustrates operations of Step 260 of FIG. 2 for obtaining at least one critical point.

FIG. 10 illustrates a portion of the circuit design associated with the critical points.

### DETAILED DESCRIPTION

According to embodiments, an IC (integrated circuit) can be operated in a functional mode and a test mode. When the IC is operated in the test mode, the flip-flops inside the IC can be coupled through a plurality of scan-chains for testing. Test patterns generated for the scan-chains can be input to the IC from the scan-in pins of the IC, and the test result (for example, recorded in a log file) can be output and observed through the scan-out pins of the IC. Since the scan-chains can couple most of the flip-flops inside the IC (e.g. up to more than 95% of the flip-flops), testing through scan-chains can achieve very high test coverage. When test patterns are applied using the on-chip clock (OCC), the test results are observed during shift out test cycles. According to embodiments, in a test result of an IC, the combination of each scan-out pin and each test cycle can be regarded as a “sensor position”, for example, expressed as [SOx, CYy], where x and y can be indexes indicating the sensor position corresponding to an xth scan-out pin and a yth test cycle. Each sensor position (e.g. [SOx, CYy]) of an IC can be used to indicate a flip-flop within the IC, or a group of flip-flops clustered and located in a small region of the IC. Moreover, in the absence of a scan-compression architecture, each sensor position may be associated with a single flip-flop. However, when a scan-compression architecture is implemented, each sensor position may correspond to a group of flip-flops.

When test patterns are input into an IC, the correct output values can be estimated in advance. However, after actually inputting test patterns into the IC, the value output by the IC may not be the same as the expected output value, so “mismatch” may occur. A test device 100 and a test method 200 described below can be used to observe the mismatch counts of the sensor positions in the test results of a plurality of sample chips to find critical points of the circuit design which are sensitive to operating voltage. In the text, a mismatch count can be abbreviated as an “MMC”. The critical points can be researched for improving the circuit design. The test device 100 and the test method 200 are not used for finding problems related to manufacturing defects, but to find manufactured sample chips that are less affected by manufacturing defects, and use these sample chips to identify real critical points related to the circuit design. Throughout a testing process, test voltage(s) provided to the sample chips may be reduced to fall below a specific voltage level. Additionally, at least one test frequency may be set to surpass a predetermined frequency. This can create a stressed condition, facilitating the occurrence of mismatches and aiding in the identification of critical points.

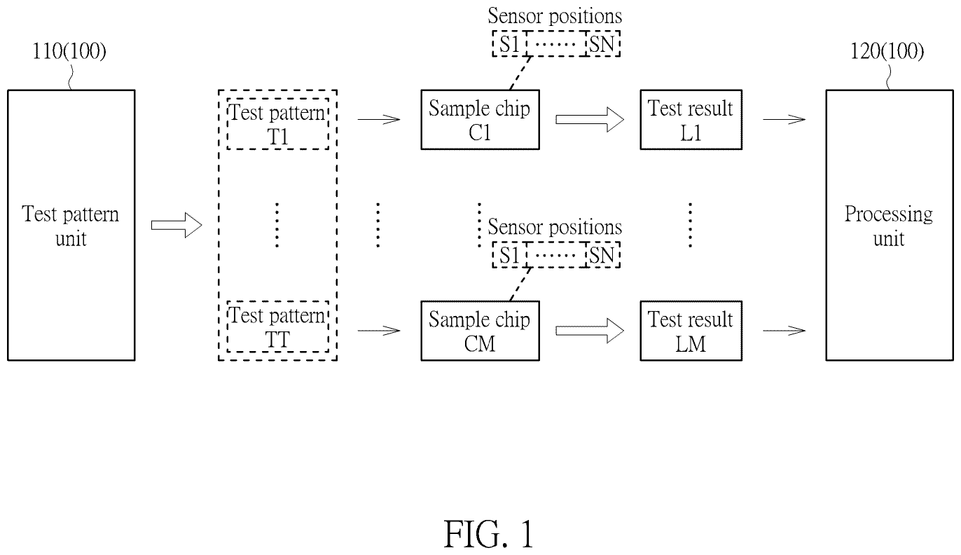

FIG. 1 illustrates a test device 100 for testing a circuit design according to an embodiment. The test device 100 can include a test pattern unit 110 and a processing unit 120. The test pattern unit 110 can be used to input T test patterns T1 to TT into M sample chips C1 to CM to generate M test results L1 to LM. The sample chips C1 to CM can be physical chips produced through the silicon process and are in the post-silicon stage. The sample chips C1 to CM can be implemented with the same circuit design, but due to process deviations, the hardware characteristics of the sample chips C1 to CM should not be exactly the same. Each sample chip of the sample chips C1 to CM can have N sensor positions S1 to SN. The test patterns T1 to TT can be automatic test pattern generation (ATPG) patterns generated for the scan-chains architecture of the sample chips C1 to CM. Each of the test results L1 to LM can be recorded in a log file. For example, after inputting the test patterns T1 to TT into the first sample chip C1, the first test result L1 (e.g. log file) can be generated. After inputting the test patterns T1 to TT into the second sample chip C2, the second test result L2 (e.g. log file) can be generated, and so on.

The processing unit 120 can be used to receive the test results LI to LM and obtain at least one critical point of the circuit design, as described below. The processing unit 120 may include a central processing unit (CPU), a graphics processing unit (GPU), a microprocessor, and/or other circuits capable of computing and analyzing data.

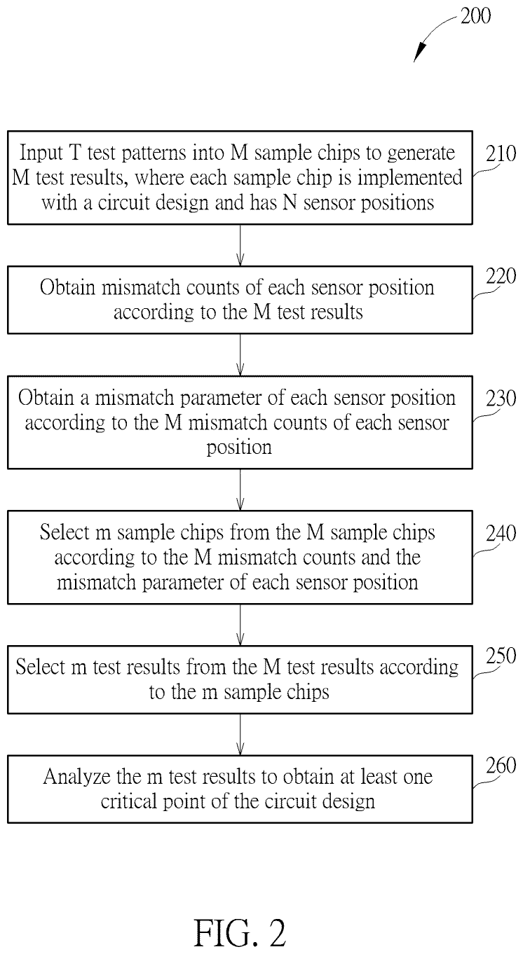

FIG. 2 illustrates a test method 200 for the test device 100 of FIG. 1. The test method 200 can include the following steps.

Step 210: input the T test patterns T1 to TT into the M sample chips C1 to CM to generate the M test results L1 to LM, where each sample chip is implemented with the circuit design and has N sensor positions S1 to SN;

Step 220: obtain M mismatch counts of each sensor position according to the M test results L1 to LM;

Step 230: obtain a mismatch parameter of each sensor position according to the M mismatch counts of each sensor position;

Step 240: select m sample chips from the M sample chips C1 to CM according to the M mismatch counts and the mismatch parameter of each sensor position;

Step 250: select m test results from the M test results L1 to LM according to the m sample chips (selected in Step 240); and

Step 260: analyze the m test results to obtain at least one critical point of the circuit design.

In FIG. 1 and FIG. 2, M>m, and T, M, N and m are positive integers. In Step 210, the sample chips C1 to CM can be used for verification of the post-silicon stage. The number of the sensor positions can be determined by the number of the scan-out pins and the number of the test cycles. For example, the N sensor positions S1 to SN can be generated according to n1 scan-out pins and n2 test cycles, n1 and n2 are positive integers, and N can be the product of n1 and n2 (i.e. N=n1×n2). The number of the test cycles (e.g. n2) can be determined according to the length of a scan chain of the sample chips C1 to CM.

In order to test the sensitivity to operating voltage and the impact on the reduction of timing margin, when the test patterns T1 to TT are inputted into the sample chips C1 to CM, at least one test voltage supplied to the sample chips C1 to CM can be lowered to be less than a predetermined voltage level, and/or at least one test frequency used for the sample chips C1 to CM can be set to exceed a predetermined frequency.

Below, Table 1 provides a simplified example to describe the mismatch counts mentioned in Step 220. In the example of Table 1, there are four sample chips C11 to C14, and six sensor positions S11 to S16. Each sample chip has six sensor positions S11 to S16, and each sensor position corresponds to the four sample chips C11 to C14. Table 1 can be obtained according to the test results of inputting the test patterns into the sample chips C11 to C14. In Table 1, each mismatch count of each sensor position for each sample chip is described. For example, the mismatch count of the sensor position S11 of the ample chip C11 is 433, the mismatch count of the sensor position S12 of the ample chip C11 is 138, the mismatch count of the sensor position S11 of the ample chip C12 is 809, and so on.

Regarding the mismatch parameter mentioned in Step 230, the example of Table 1 can be referred to. Since each sensor position corresponds to a plurality of mismatch counts of different sample chips, a mismatch parameter of each sensor position can be obtained. As shown by arrows in Table 1, a mismatch parameter of the sensor position S11 can be obtained according to mismatch counts 433, 809, 49 and 1729; a mismatch parameter of the sensor position S12 can be obtained according to mismatch counts 138, 171, 0 and 305; and so on.

Table 1 is merely a simplified example to describe the relationship of the sensor position, the sample chips, and the mismatch counts. In a more realistic example, there may be nearly 90,000 test patterns, 100 to 500 sample chips, and nearly 9,000 sensor positions, but embodiment are not limited thereto.

In Step 230, the mismatch parameter of each sensor position can be a median (i.e. second quartile Q2) of the mismatch counts of the sensor position. However, depending on the requirements, a formula can be adjusted to generate the mismatch parameter with mismatch counts of a sensor position. For example, a function can be used to generate a mismatch parameter of a sensor position based on a median (i.e. second quartile Q2), a mean, or another parameter of mismatch counts of the sensor position.

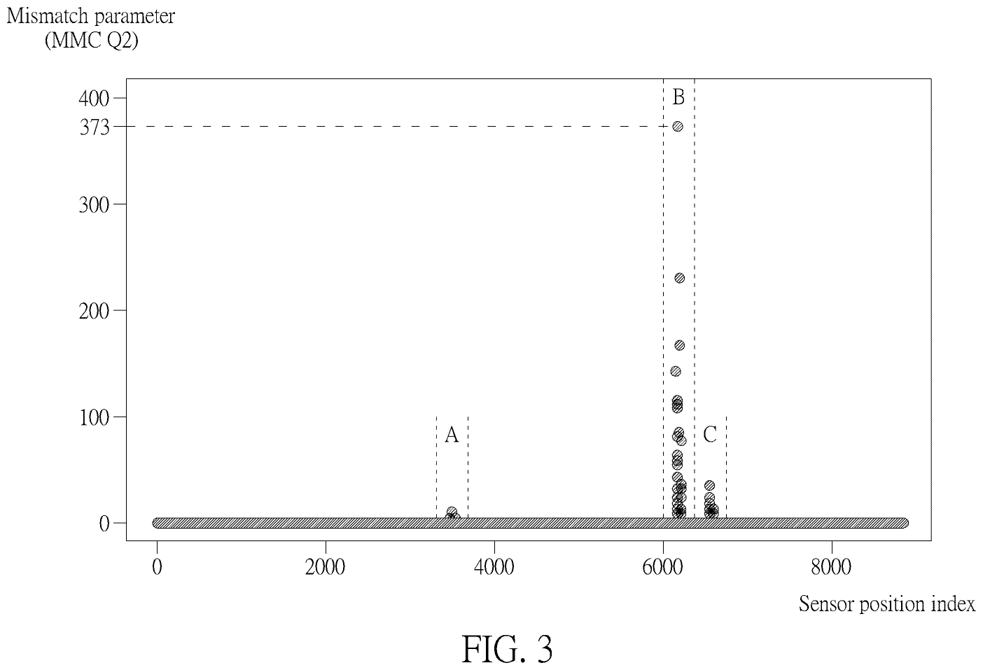

FIG. 3 shows a distribution of mismatch parameters of mismatch counts of 8855 sensor positions in an example. In FIG. 3, a mismatch parameter corresponding to a sensor position can be the median of mismatch counts of the sensor position. The median of mismatch counts can be denoted as “MMC Q2”. FIG. 3 provides a MMC Q2 profile at the 8855 sensor positions. In FIG. 3, the horizontal axis represents the indexes of the first sensor position to the 8855th sensor position. The vertical axis represents the medians of the mismatch counts of the sensor positions. Each sensor position can be corresponding to a median of mismatch counts in FIG. 3. As shown in FIG. 3, mismatch parameters (i.e. the medians of the mismatch counts) of most sensor positions are close to 0. However, some sensor positions may have larger mismatch parameters. For example, the sensor positions located in windows A, B and C are observed to have large mismatch parameters. A sensor position located in the window B even has an MMC Q2 up to 373. A sensor position with a high mismatch parameter (e.g. 373) may have non-monotonic behavior, and the circuit point(s) corresponding to the sensor position may have a tight timing margin.

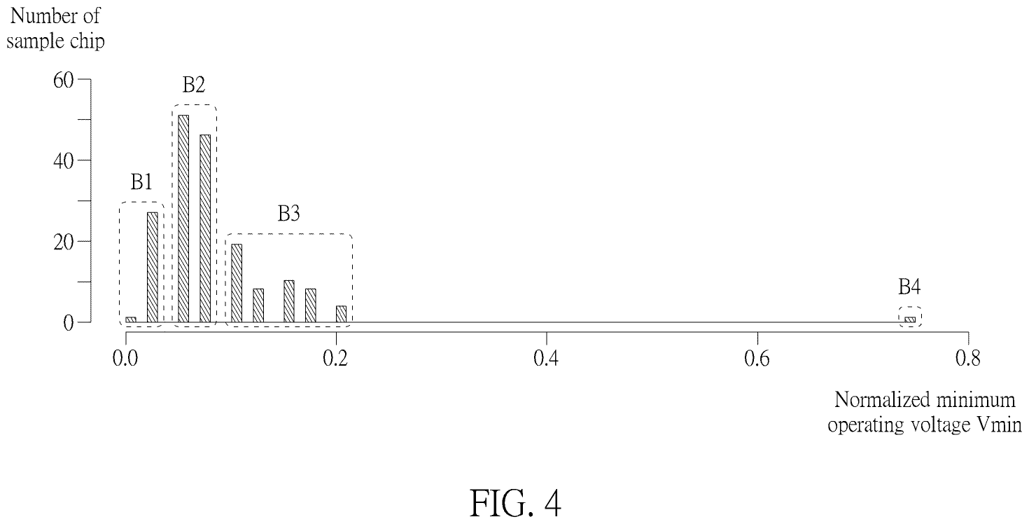

Regarding the selection of the sample chips mentioned in Step 240 of FIG. 2, FIG. 4 to FIG. 8 provide an example. FIG. 4 illustrates a distribution of the sample chips C1 to CM of FIG. 1 according to the minimum operating voltages Vmin of the sample chips. The minimum operating voltages Vmin of the sample chips can be obtained through actual measurement using predetermined patterns (e.g. functional patterns). In FIG. 4, the horizontal axis represents the normalized minimum operating voltages Vmin of the sample chips C1 to CM, and the vertical axis represents the corresponding numbers of sample chips. In FIG. 4, the normalized minimum operating voltages Vmin are normalized to be between 0 and 1. As shown in FIG. 4, the sample chips can be classified to a first bin B1, a second bin B2, a third bin B3, and a fourth bin B4. In this example, the sample chips in the bin B1 can account for 16% of all sample chips. The sample chips in the bin B2 can account for 55% of all sample chips. The sample chips in the bin B3 can account for 28% of all sample chips. The sample chips in the bin B4 can account for 0.6% of all sample chips.

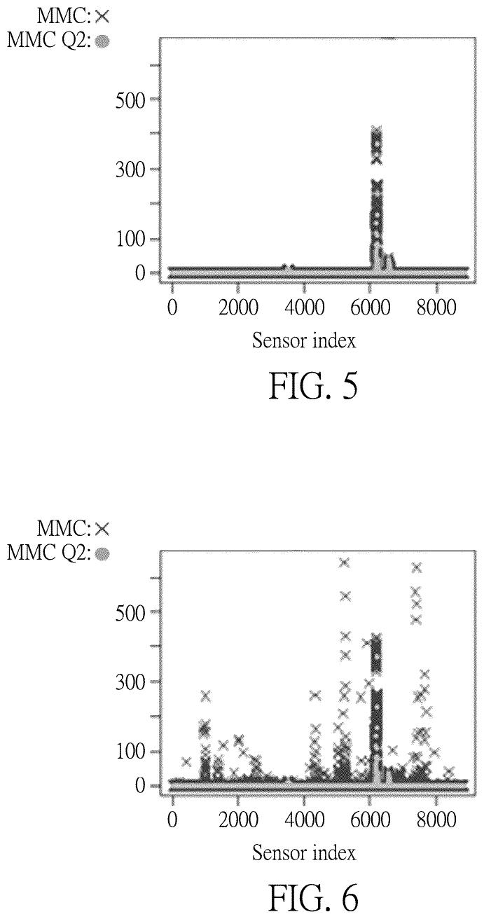

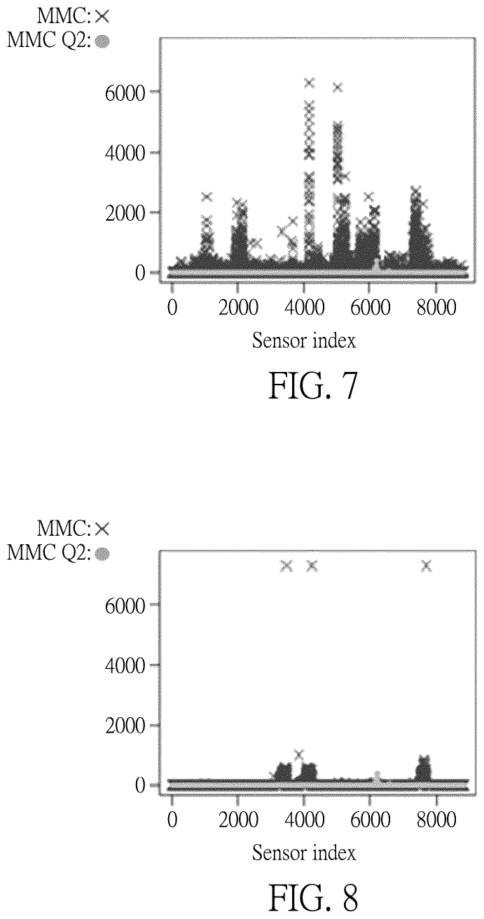

FIG. 5 displays distributions of mismatch parameters and mismatch counts for 8855 sensor positions of the sample chips in the bin B1 of FIG. 4. FIG. 6 displays distributions of mismatch parameters and mismatch counts for 8855 sensor positions of the sample chips in the bin B2 of FIG. 4. FIG. 7 displays distributions of mismatch parameters and mismatch counts for 8855 sensor positions of the sample chips in the bin B3 of FIG. 4. FIG. 8 displays distributions of mismatch parameters and mismatch counts for 8855 sensor positions of the sample chips in the bin B4 of FIG. 4. A mismatch parameter can be the median of mismatch counts (MMC Q2). FIG. 5 to FIG. 8 are the MMC profile diagrams of the sample chips in the bins BI to B4 respectively. In FIG. 5 to FIG. 8, the horizontal axis denotes the indexes of the sensor positions, ranging from the first to the 8855th sensor position. The vertical axis represents the mismatch counts and the mismatch parameters (e.g., MMC Q2s) of the sensor positions. The mismatch counts are marked with “x” symbols, and the mismatch parameters (e.g., MMC Q2s) are denoted with dots. However, due to the large number of dots and “x” symbols, it may be challenging to visually distinguish each dot and symbol “x”

As shown in FIG. 5, the distribution of the mismatch counts (denoted with symbols “x”) is highly consistent with the distribution of the mismatch parameters (e.g. MMC Q2s, marked with dots). Therefore, it can be determined that the relevant chips (i.e. the sample chips in the bin BI of FIG. 4) are less affected by the defects and variations of the manufacturing process, but are affected by the circuit design. The test device 100 and the test method 200 are used to identify critical points of the circuit design and aim to mitigate the impact of the manufacturing process. Therefore, the sample chips associated with FIG. 5 (e.g. the sample chips in the bin B1 of FIG. 4) can be selected in Step 240 of FIG. 2.

In FIG. 6 to FIG. 8, the distribution of mismatch counts (marked with symbols “x”) significantly deviates from the distribution of mismatch parameters (e.g. MMC Q2s, marked with dots). This inconsistency suggests that the corresponding sample chips might be impacted by manufacturing defects or variations. Therefore, the sample chips associated with FIG. 6 to FIG. 8 (such as those sample chips in the bins B2 to B4 of FIG. 4) are not selected in Step 240.

Consider FIG. 8 as an example. The minimum operating voltages (Vmin) are exceptionally high, and the MMC values are also large. Please note that the unit of the vertical axis in FIG. 8 is already tenfold compared to that in FIG. 5. This indicates that the sample chips related to FIG. 8 are likely to possess manufacturing defects, rendering them unsuitable for analyzing the critical points of the circuit design.

FIG. 3 to FIG. 8 serve as an example, and embodiments are not limited thereto. In the example in FIG. 3 to FIG. 8, the sample chips associated with FIG. 5 can be selected in Step 240 of FIG. 2. However, in alternative embodiments, a sample chip can be selected in Step 240 of FIG. 2 if a certain proportion or all of the sensor positions on the sample chip have MMCs that do not deviate significantly from the corresponding MMC parameters (e.g. MMC Q2s). For example, a sample chip can be selected in Step 240 of FIG. 2 if all the MMCs of each sensor position fall within the first quartile (often referred to as Q1) and the third quartile (often referred to as Q3) of the MMCs.

After selecting m sample chips in Step 240 of FIG. 2, in Step 250, m test results (e.g. failure log files) of the M test results generated in Step 210 can be chosen for Step 260.

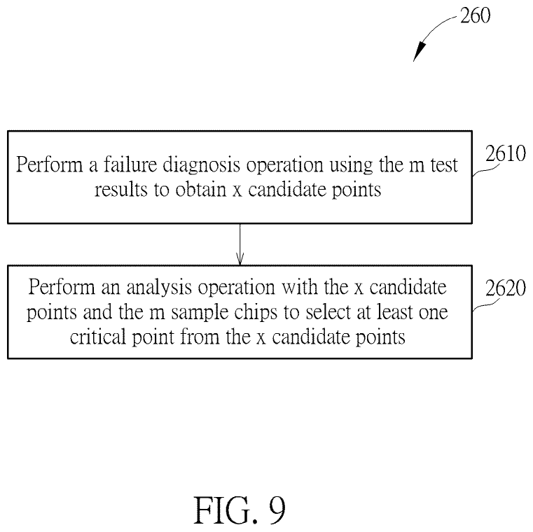

FIG. 9 illustrates operations of Step 260 of FIG. 2. Step 260 may include the following steps.

Step 2610: perform a failure diagnosis operation using the m test results to obtain x candidate points; and

Step 2620: perform an analysis operation with the x candidate points and the m sample chips to select at least one critical point from the x candidate points.

In FIG. 9, x can be a positive integer. Below, in an example, m=151 and x=14. In other words, 151 sample chips can be selected in Step 240, and 14 candidate points can be obtained in Step 2610, in this example. In Step 2610, the 151 test results (e.g. log files) related to the 151 selected sample chips (e.g. the sample chips of the bin B1 of FIG. 4) are used to perform the failure diagnosis operation to find the 14 candidate points. These 14 candidate points can be the circuit positions contributing to failure symptoms. A hierarchical representation can be used to indicate a circuit location corresponding to a candidate point. For example, a candidate point described as “u_11/u_115/FF2/pin_11” can indicate a pin pin_11 of a flip-flop FF2 in a block u_115 in a block u_11 of the circuit design. Hence, in Step 2610, x (e.g. 14) circuit locations that may be more sensitive to the operating voltage can be found. In Step 2620, the x (e.g. 14) candidate points of the m (e.g. 151) sample chips can be analyzed to select least one critical point.

In Step 2620, a Pareto analysis operation can be performed to select the least one critical point from the x candidate points. In other embodiments, other suitable analysis methods for identifying the most significant factors in a set of data may be used.

For example, upon analyzing the test results of the 151 selected sample chips, it was found that among the 14 candidate points, three candidate points are identified to be associated with the failure of 148 out of the 151 sample chips. Since these 148 sample chips constitute over 98% of the 151 sample chips, these 3 candidate points are selected as critical points in Step 2620.

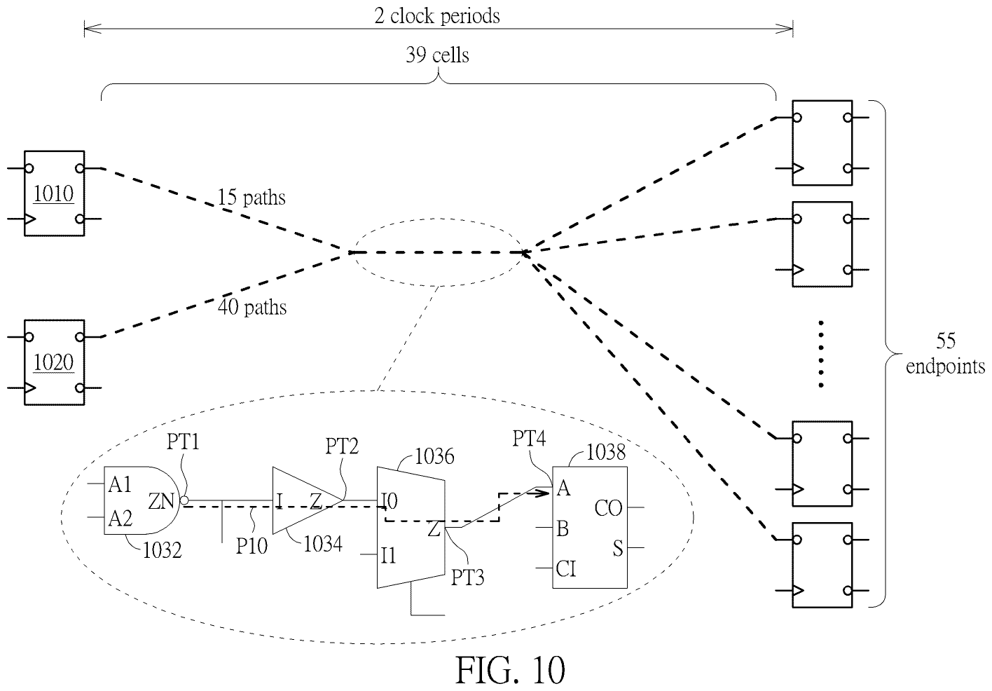

In addition, among the 14 candidate points, another one candidate point is identified to be associated with the failure of 99 out of the 151 sample chips. Since these 99 sample chips constitute over 65% of the 151 sample chips, the candidate point is selected as critical point in Step 2620. Hence, in this example, four critical points can be selected in Step 2620. In FIG. 10, the four critical points can be denoted as PT1 to PT4.

After identifying at least one critical point (for instance, 4 critical points as mentioned in the example), the timing paths passing through these critical points can be examined using tools like a static timing analysis (STA) tool. This analysis helps in identifying timing violations such as hold-time violations and set-up time violations of the paths. FIG. 10 depicts a portion of the circuit design associated with the critical points identified in the example. As mentioned in the preceding example, four critical points (denoted as PT1, PT2, PT3 and PT4 in FIG. 10) can be obtained. The four critical points PT1 to PT4 can be located within a small region and related to a set of clustered components in the circuit design. In addition, the four critical points PT1 to PT4 can be located along a path P10.

In the example of FIG. 10, 15 paths starting from a flip-flop 1010 can pass through the path P10, and 40 paths starting from a flip-flop 1020 can pass through the path P10. The 55 paths starting from the flip-flop 1010 and the flip-flop 1020 can have 55 endpoints at 55 flip-flops. The 55 paths starting from flip-flop 1010 and flip-flop 1020 can transmit signals from the starting points to the endpoints within 2 clock periods. The 55 paths can pass through 39 cells. Among the 39 cells, four cells can be related to the critical points PT1 to PT4. The critical point PT1 can be located at an output terminal of a cell 1032 (e.g. AND-gate). The critical point PT2 can be located at an output terminal of a cell 1034 (e.g. buffer). The critical point PT3 can be located at an output terminal of a cell 1036 (e.g. multiplexer). The critical point PT4 can be located at one input terminal of a cell 1038 (e.g. full-adder).

Hence, it can be inferred that the four critical points PT1 to PT4 and the path P10 in FIG. 10 could be sensitive to operating voltage. The circuit design can be enhanced by investigating and optimizing the four critical points PT1 to PT4 and the path P10. This can lead to a reduction in the minimum operating voltage Vmin. Consequently, the circuit design can function normally with a lower operating voltage.

In FIG. 10, the critical points PT1 to PT4 and the path P10 are merely of an example. In another circuit design, different numbers of critical points and paths may be discovered.

As a result, the test device 100 and the test method 200 can identify critical points and paths that are sensitive to operating voltage in the post-silicon stage. According to experiments, it is highly likely that these critical points and paths cannot be discovered during the pre-silicon stage. Since the test device 100 and the test method 200 utilize the existing scan-chain architecture of the sample chips, there is no additional hardware overhead. Hence, the test device 100 and the test method 200 can effectively find real critical points of a circuit design in a post-silicon stage with high accuracy and high coverage.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A test method for testing a circuit design, comprising:
inputting T test patterns into M sample chips to generate M test results, wherein each sample chip is implemented with the circuit design and has N sensor positions;
obtaining M mismatch counts of each sensor position according to the M test results;
obtaining a mismatch parameter of the each sensor position according to the M mismatch counts of the each sensor position;
selecting m sample chips from the M sample chips according to the M mismatch counts and the mismatch parameter of the each sensor position;
selecting m test results from the M test results according to the m sample chips; and
analyzing the m test results to obtain at least one critical point of the circuit design;
wherein M>m, and T, M, N and m are positive integers.

2. The test method of claim 1, wherein the T test patterns are automatic test pattern generation (ATPG) patterns.

3. The test method of claim 1, wherein the N sensor positions are generated according to n1 scan-out pins and n2 test cycles, n1 and n2 are positive integers, and N is a product of n1 and n2.

4. The test method of claim 3, wherein n2 is determined according to a length of a scan chain of the M sample chips.

5. The test method of claim 1, wherein when the T test patterns are inputted into the M sample chips, at least one test voltage supplied to the M sample chips is lowered to be less than a predetermined voltage level, and/or at least one test frequency used for the M sample chips is set to exceed a predetermined frequency.

6. The test method of claim 1, wherein the mismatch parameter of the each sensor position is a median of the M mismatch counts of the each sensor position.

7. The test method of claim 1, wherein analyzing the m test results to obtain the at least one critical point of the circuit design comprises:
performing a failure diagnosis operation using the m test results to obtain x candidate points; and
performing an analysis operation with the x candidate points and the m sample chips to select the at least one critical point from the x candidate points;
wherein x is a positive integer.

8. The test method of claim 7, wherein the analysis operation is a Pareto analysis operation.

9. A test device for testing a circuit design, comprising:
a test pattern unit configured to input T test patterns into M sample chips to generate M test results, wherein the M sample chips are implemented with the circuit design, and each sample chip has N sensor positions; and
a processing unit configured to receive the M test results, obtain M mismatch counts of each sensor position according to the M test results, obtain a mismatch parameter of the each sensor position according to the M mismatch counts of the each sensor position, select m sample chips from the M sample chips according to the M mismatch counts and the mismatch parameter of the each sensor position, select m test results from the M test results according to the m sample chips, and analyze the m test results to obtain at least one critical point of the circuit design;
wherein M>m, and T, M, N and m are positive integers.

10. The test device of claim 9, wherein the N sensor positions are generated according to n1 scan-out pins and n2 test cycles, n1 and n2 are positive integers, N is a product of n1 and n2, and n2 is determined according to a length of a scan chain of the M sample chips.
